(19) United States
(12) Patent Application Publication
(10) Pub. No.: US 2024/0006196 A1
(43) Pub. Date: Jan. 4, 2024

(54) BONDING MACHINE FOR WARPED SUBSTRATES

(71) Applicant: SKY TECH INC., Hsinchu County (TW)

(72) Inventors: JING-CHENG LIN, Hsinchu County (TW); JUNG-HUA CHANG, Hsinchu County (TW)

(21) Appl. No.: 17/853,428

(22) Filed: Jun. 29, 2022

(51) Int. Cl. H01L 21/67

(52) U.S. Cl. CPC H01L 21/67092

(57) ABSTRACT

The disclosure is a bonding machine for warped substrates, which includes a first chamber, a second chamber, a pressing unit, a carrier and a plurality of flattening devices. The first chamber is configured to connect with the second chamber to define an enclosed space therebetween. The pressing unit is connected to the first chamber, and the carrier is connected to the second chamber. The pressing unit faces the carrier and is configured to bond the substrates placed on the carrier. The flattening devices are arranged on the carrier, and include a plurality of flattening units and a plurality of telescopic rotary motors. The flattening units are located around the substrate. The telescopic rotation motor is connected to and drives the flattening unit to rotate, move up and down to flatten the substrate placed on the carrier to improve the accuracy of aligning the substrate.

### BACKGROUND

### Technical Field

The disclosure is a bonding machine for warped substrates, which is able to flatten a substrate placed on a carrier by flattening units to improve the accuracy of aligning the substrate.

### Related Art

The integrated circuit technology has been well developed. At present, electronic products are developing towards the trend of being light and thin, and having high performance, high reliability and intelligence. The chip in an electronic product can have a significant impact on the performance of the electronic product, wherein the performance is partly related to the thickness of the chip. For example, thinner chips can improve heat dissipation efficiency, increase mechanical performance, improve electrical properties, and reduce package size and weight.

In the semiconductor process, the substrate thinning process, the via etching process, and the backside metallization process are usually performed on the backside (e.g., lower surface) of the wafer. In generally, a bonding process is performed before the substrate thinning process. The bonding process mainly arranges a bonding layer between the wafer and the carrier substrate (e.g., sapphire substrate), and presses the stacked wafer and carrier substrate by using a pressing unit and a carrier (e.g., chuck), so as to bonding the wafer and the carrier substrate. After the substrate thinning process, a debonding process is performed, to separate the wafer and the carrier substrate.

However, the expansion coefficients of the material layers of the wafer may be different, so the wafer is often subject to warpage after a high temperature process. In addition, wafers may have different warpage shapes, such as saddle-shaped, hill-shaped protrusions, etc., which is not conducive to alignment of the stacked wafers and the carrier substrate during the bonding process.

### SUMMARY

In order to solve the above-mentioned problems, this disclosure provides a novel bonding machine for warped substrates. The bonding machine comprises a plurality of flattening devices for flattening a warped substrate placed on a carrier surface of a carrier. Thereafter, the flattened substrate is aligned by an alignment unit to improve the accuracy of aligning the warped substrate.

An object of this disclosure is to provide a bonding machine for warped substrates, which includes a first chamber, a second chamber, a pressing unit, a carrier and a plurality of flattening devices. The first chamber is configured to be connected to the second chamber to define an enclosed space therebetween.

The flattening devices are arranged on the carrier. Each flattening device includes a telescopic rotary motor and a flattening unit. The flattening units are arranged around the substrate. The telescopic rotary motor is connected to and drives the flattening unit to rotate, move up and down relative to the carrier surface of the carrier.

In practical application, the substrate is placed on the carrier surface of the carrier, and the telescopic rotary motor drives the raised flattening unit to rotate to located above the substrate. When the telescopic rotary motor drives the flattening unit to rotate, there is a gap between the flattening unit and the substrate to avoid abrasion of the substrate during the rotation. Therefore, the telescopic rotary motor drives the flattening unit to move down and approach the substrate to flatten the warped substrate, and then align the substrate through a plurality of alignment units.

During the process of aligning the substrate by the alignment unit, the flattening units continuously press the substrate and keep the substrate flat, so that the alignment unit can align the flattened substrate to improve accuracy of the alignment of the substrate.

An object of this disclosure is to provide a bonding machine for warped substrates, which includes a plurality of flattening devices, a plurality of alignment units, and a plurality of exhaust lines on the carrier surface of the carrier. The exhaust lines are connected to the carrier surface of the carrier, and are located below the substrate to suck an inner side of the warped substrate. The flattening devices and the alignment units are located around the substrate, wherein the flattening units are able to move up, rotate and move down relative to the substrate to flatten a side edge of the warped substrate. The alignment units are close to the substrate along the radial direction of the carrier surface to align the flattened substrate

To achieve the object, this disclosure provides a bonding machine for warped substrates, which comprises; a first chamber; a second chamber facing the first chamber, wherein the first chamber is configured to be connected the second chamber to define an enclosed space between the first chamber and the second chamber; a pressing unit connected to the first chamber and located within the enclosed space; a carrier connected to the second chamber, and located within the enclosed space, wherein the carrier includes a carrier surface facing the pressing unit, wherein the carrier surface includes a placement area is configured to carry a first substrate, and a second substrate is placed on the first substrate; and a plurality of flattening devices, including: a plurality of flattening units located around the placement area of the carrier; a plurality of telescopic rotary motors connected to the flattening units, and driving the flattening units to swing, move up and down relative to the carrier surface of the carrier, so that the flattening units are configured to flatten the first substrate on the placement area.

### BRIEF DESCRIPTION OF THE DRAWINGS

This disclosure will become more fully understood from the detailed description given herein below for illustration only, and thus not limitative of this disclosure, wherein:

FIG. 1 is a three-dimensional view of a bonding machine for warped substrates according to an embodiment of this disclosure.

FIG. 2 is a cross-sectional view of the bonding machine for warped substrates according to the embodiment of this disclosure.

FIG. 3 is a partial cross-sectional view of the bonding machine for warped substrates according to the embodiment of this disclosure.

FIG. 4 is a three-dimensional view of a carrier and flattening devices of the bonding machine for warped substrates according to an embodiment of this disclosure.

FIG. 5 is a top view of the carrier and flattening units of the bonding machine for warped substrates according to an embodiment of this disclosure.

FIG. 6 is a top view of the carrier and flattening units of the bonding machine for warped substrates according to another embodiment of this disclosure.

FIG. 7 is a three-dimensional view of the carrier and flattening devices of the bonding machine for warped substrates according to the embodiment of this disclosure.

FIG. 8 is a three-dimensional view of the carrier and flattening devices of the bonding machine for warped substrates according to the embodiment of this disclosure.

FIG. 9 is a cross-sectional view of the carrier, the flattening devices and exhaust lines of the bonding machine for warped substrates according to the embodiment of this disclosure.

### DETAILED DESCRIPTION

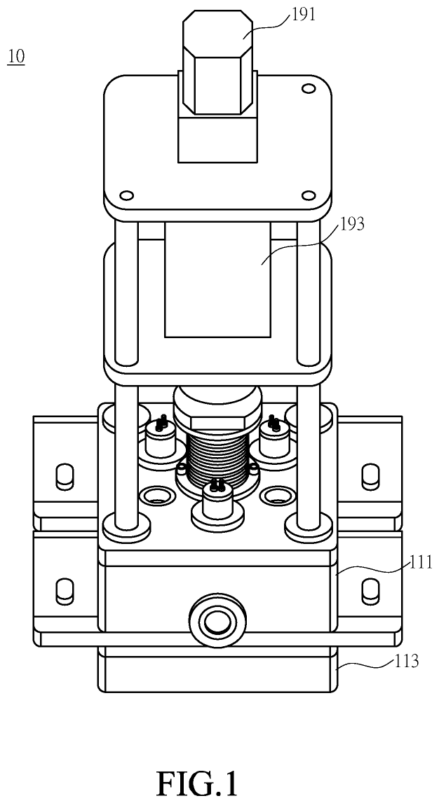

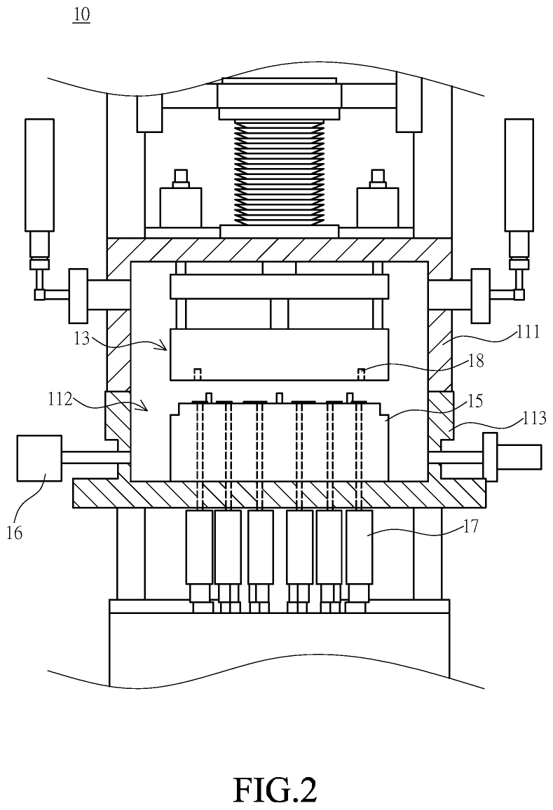

FIG. 1 and FIG. 2 are respectively a three-dimensional view and a cross-sectional view of a bonding machine for warped substrates according to an embodiment of this disclosure. As shown in drawings, the bonding machine 10 includes a first chamber 111, a second chamber 113, a pressing unit 13, a carrier 15 and a plurality of flattening devices 17. The first chamber 111 faces the second chamber 113, and the first chamber 111 is configured to move with respect to the second chamber 113.

As shown in FIG. 2, the pressing unit 13 is disposed within the first chamber 111 and connected to the first chamber 111. The carrier 15 is located within the second chamber 113 and connected to the second chamber 113. A carrying surface 151 of the carrier 15 faces the pressing unit 13. After the first chamber 111 is connected to the second chamber 113, an enclosed space 112 is defined therebetween, and the pressing unit 13 and the carrier are located within the enclosed space 112.

As shown in FIG. 1, in at least one embodiment of this disclosure, the first chamber 111 is connected to a chamber driver 191. The chamber driver 191 is located outside the enclosed space 112 and connected to the first chamber 111. The chamber driver 191 is configured to drive the first chamber 111 to move with respect to the second chamber 113. In an example, the chamber driver 191 is a linear actuator.

Moreover, a pressing unit driver 193 is disposed outside the enclosed space 112 and connected to the pressing unit 13. In an example, the pressing unit driver 193 is a linear actuator, and configured to drive the pressing unit 13 to move toward or to move away from the carrier 15. After alignment of a first substrate 121 with a second substrate 123, the pressing unit driver 193 drives the pressing unit 13 to move toward the carrying surface 151 of the carrier 15 to press the first substrate 121 and the second substrate 123 on the carrier so as to bond the first substrate 121 and the second substrate 123.

As shown in FIG. 2, an air extraction motor 16 is connected to the first chamber 111 or the second chamber 113. The air extraction motor 16 is fluidly connected to the enclosed space 112 and configured to extract air within the enclosed space 112, to reduce pressure in the enclosed space 112, so as to have the enclosed space 112 in a low pressure or vacuum state.

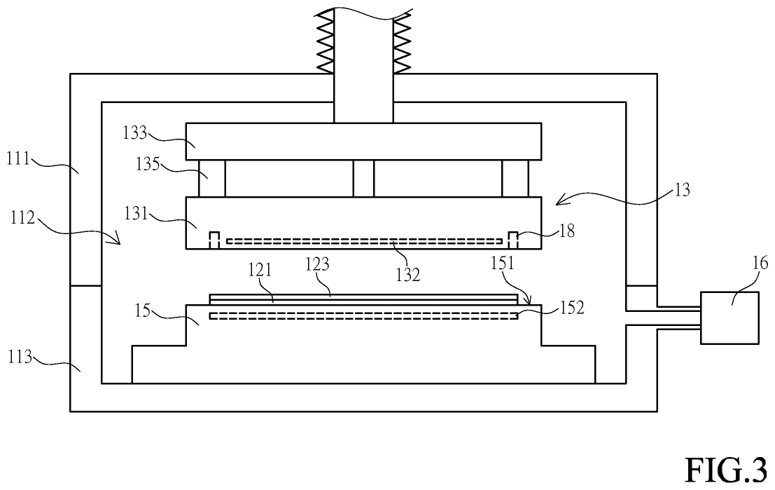

As shown in FIG. 3, the carrying surface 151 of the carrier 15 is configured to carry the first substrate 121 and the second substrate 123 stacked on the carrying surface. In an example the first substrate 121 is a carrier substrate, the second substrate 123 is a wafer, and an adhesive layer is provided between the first substrate 121 and the second substrate 113 to bond the first substrate 121 and the second substrate 123. In another example, the first substrate 121 and the second substrate 123 are wafers that have undergone semiconductor processes.

The pressing unit 13 includes a pressing plate 131, a connecting plate 133 and a plurality of fixing rods 135. The connecting plate 133 is connected to the pressing plate 131 through the fixing rods 135. The pressing plate 131 faces the carrying surface 151 of the carrier 15 and is configured to press the first substrate 121 and the second substrate 123 on the carrier 15. The pressing unit 13 including the pressing plate 131, the connecting plate 133 and the fixing rods 135 is merely an example of this disclosure not a restrict limitation.

In at least one embodiment of this disclosure, a first heating unit 152 is disposed within the carrier 15, and a second heating unit 132 is disposed within the pressing unit 13. During bonding, the first heating unit 152 and the second heating unit 132 are able to heat the first substrate 121, the second substrate 123 and the adhesive layer between the pressing unit 13 and the carrier 15.

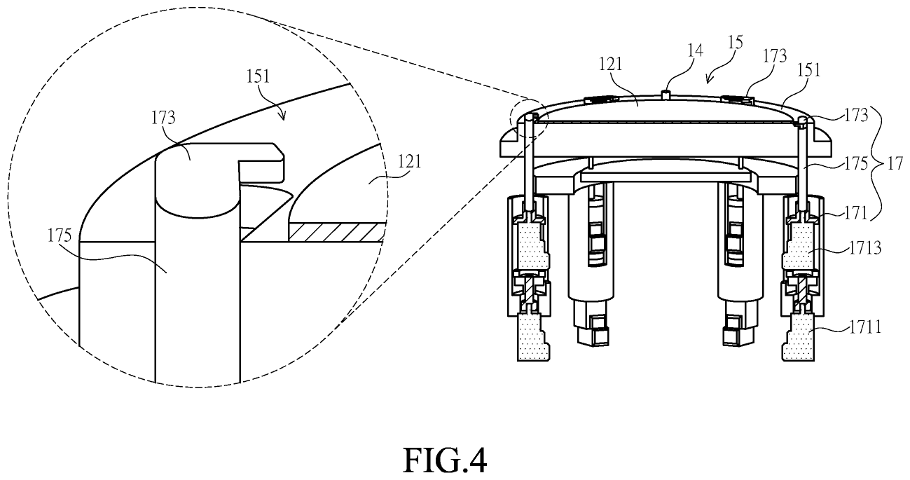

As shown in FIG. 2 and FIG. 4, each flattening device 17 includes a telescopic rotary motor 171 and a flattening unit 173, wherein the telescopic rotary motor 171 is connected to and drives the flattening unit 173 to swing, move up and down relative to the carrier surface 151 of the carrier 15.

In one embodiment of this disclosure, the telescopic rotary motor 171 may include a linear actuator 1711 and a rotation motor 1713, wherein the linear actuator 1711 is connected to the flattening unit 173 via the rotation motor 1713. The linear actuator 1711 is configured to drive the rotation motor 1713 and the flattening unit 173 to move up and down relative to the carrier surface 151 of the carrier 15, and the rotation motor 1713 is configured to drive the flattening unit 173 to swing relative to the carrier surface 151 of the carrier 15.

The telescopic rotary motor 171 is located outside the enclosed space 112, and the flattening unit 173 is located within the enclosed space 112. In one embodiment of this disclosure, the telescopic rotary motor 171 is connected to and drives the flattening unit 173 to swing, move up and down via a rod 175, wherein the rod 175 passes through the second chamber 113 and/or the carrier 15. In addition, a shaft seal and/or bearing may be arranged between the rod 175 and the second chamber 113 and/or the carrier 15, so that the rod 175 can rotate, move up and down relative to the second chamber 113 and/or the carrier 15, and maintain the low pressure and vacuum state of the enclosed space 112.

The flattening units 173 are disposed on the carrier surface 151 of the carrier 15, wherein the flattening unit 173 may be a plate with any geometric shape and has a flat lower surface. In practical application, the first substrate 121 placed on the carrier surface 151 of the carrier 15 can be pressed through the flat lower surface of the flattening units 173 to flatten the warped first substrate 121.

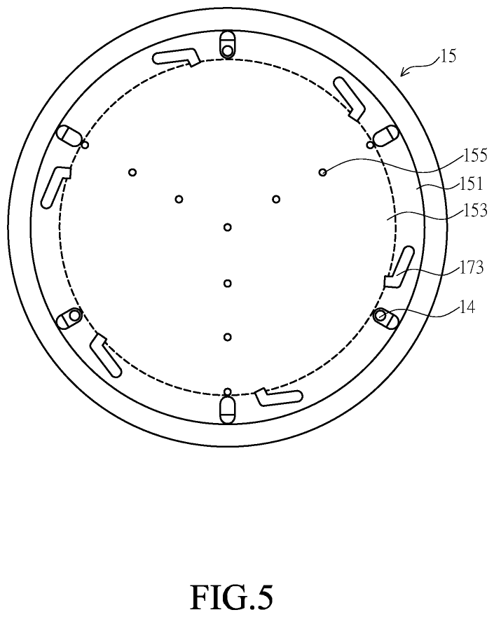

As shown in FIG. 5, a plurality of flattening units 173 are located within the enclosed space 112, and are arranged on the carrier surface 151 of the carrier 15. In one embodiment of this disclosure, a placement area 153 may be defined on the carrier surface 151 of the carrier 15, wherein the area and/or shape of the placement area 153 are approximately similar to the first substrate 121 and smaller than or equal to the carrier surface 151.

When the first substrate 121 is placed on the carrier surface 151 of the carrier 15, the first substrate 121 will be located on the placement area 153, and a plurality of flattening units 173 are located around the placement area 153.

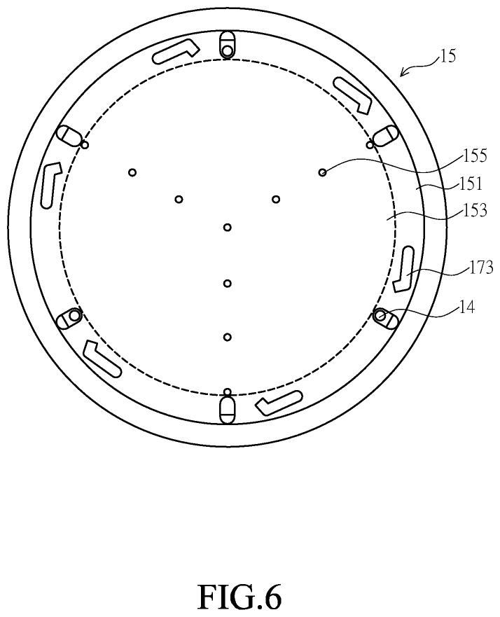

As shown in FIG. 5 and FIG. 6, the telescopic rotary motor 171 is configured to drive the flattening unit 173 to swing in the direction parallel to the carrier surface 151 of the carrier 15. In one embodiment of this disclosure, the telescopic rotary motor 171 is able to drive the flattening unit 173 to swing between a first position and a second position.

Specifically, the flattening unit 173 operating at the first position is located outside the placement area 153 of the carrier 15 without overlapping or interfering with the first substrate 121 on the placement area 153, as shown in FIG. 5. The flattening unit 173 operating at the second position enters the placement area 153 of the carrier 15 and is located above the first substrate 121 of the placement area 153, as shown in FIG. 6.

As shown in FIG. 4, during placing the first substrate 121 on the carrier surface 151 of the carrier 15, the flattening unit 173 is located at the first position. The flattening unit 173 does not interfere with the placement area 153 of the carrier surface 151, so that the first substrate 121 can be placed on the placement area 153 of the carrier surface 15 by a robot arm.

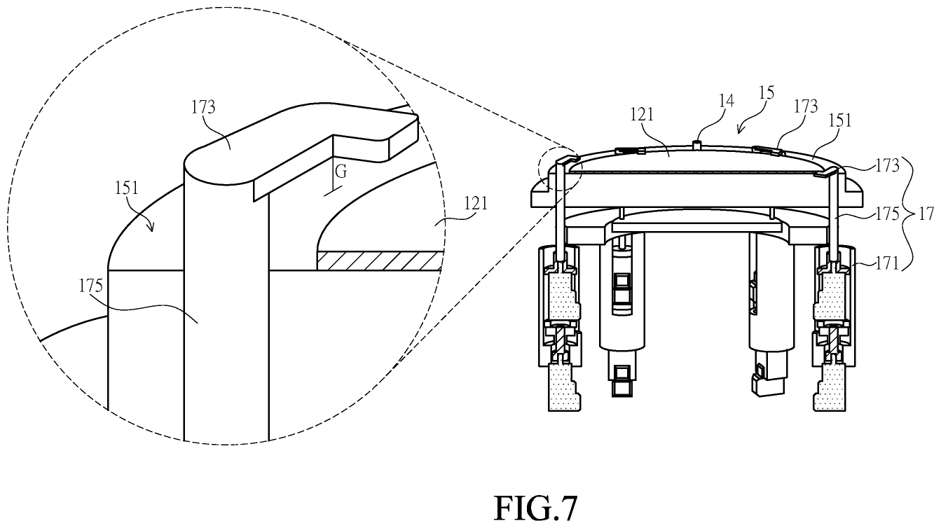

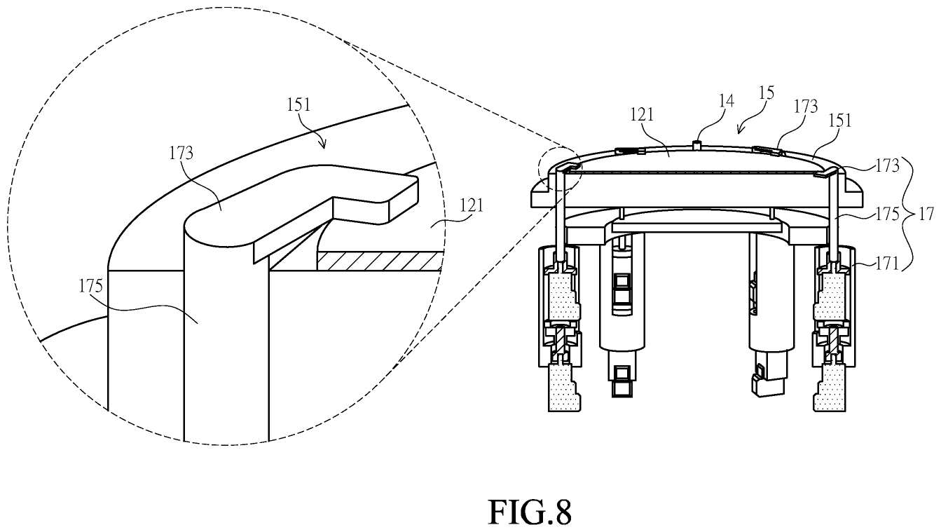

As shown in FIG. 7 and FIG. 8, the telescopic rotary motor 171 is configured to drive the flattening unit 173 to move along direction parallel to the axial direction of the carrier surface 151, and adjust the distance between the flattening unit 173 and the carrier surface 151 and/or the first substrates 121. In one embodiment of this disclosure, the telescopic rotary motor 171 is configured to drive the flattening unit 173 to move between a first height and a second height, wherein the first height is higher than the second height. For example, the flattening unit 173 located at the second height is closer to the carrier surface 151 of the carrier 15 than the flattening unit 173 located at the first height.

As shown in FIG. 7, the telescopic rotary motor 171 is configured to drive the flattening unit 173 to move along the axial direction of the carrier surface 151 and away from the carrier surface 151 of the carrier 15 to operate at the first height. There is a gap G between the flattening unit 173 and the carrier surface 151, and the gap G is greater than the thickness of the first substrate 121 plus a warpage of the first substrate 121. For example, the warpage is the distance between two points of the warpage plane of the first substrate 121 that are farthest apart in the height direction, or the maximum distance between the lower surface of the first substrate 121 and the carrier surface 151 of the carrier 15. Then, the telescopic rotary motor 171 drives the flattening unit 173 to swing along the direction parallel to the carrier surface 151, and part of the flattening unit 173 is located above the placement area 153 and the first substrate 121.

As shown in FIG. 8, the telescopic rotary motor 171 drives the flattening unit 173 to move along the axial direction of the carrier surface 151 and approach the carrier surface 151 of the carrier 15 to operate at the second height. The flattening unit 173 contacts and flattens the first substrate 121 placed on the placement area 153.

As shown in FIG. 5 and FIG. 6, a plurality of alignment units 14 may be arranged on the carrier surface 151 of the carrier 15, and the alignment units 14 surround the placement area 153 of the carrier 15. The alignment units 14 are configured to move toward or away from the first substrate 121 and the second substrate 123 on the carrier 15, to have the second substrate 123 be aligned with the first substrate 121. For example, the alignment unit 14 may be rod-shaped, and is moved up and down relative to the carrier surface 151 of the carrier 15 by a linear actuator. The alignment units 14 protruding from the carrier surface 151 are configured to approach the placement area 153 along the radial direction of the carrier surface 151, and then the alignment units 14 contact and align the first substrate 121, to have the first substrate 121 be aligned with the placement area 153.

In the process of alignment of the first substrate 121, the flattening unit 173 will continuously contact and flatten the first substrate 121, which is able to improve the accuracy of aligning the first substrate 121 via the alignment units 14.

As shown in FIG. 2 and FIG. 3, a plurality of distance measuring units 18 are arranged on the pressing unit 13. For example, the distance measuring unit 18 may be a laser rangefinder. The distance measuring units 18 are configured to project measuring beams to the first substrate 121 placed on the carrier surface 151 of the carrier 15, and measure the distances between the first substrate 121 and each distance measuring unit 18 to determine whether the first substrate 121 is warped. In other embodiments, the distance measuring units 18 may be arranged on the carrier 15. The distance measuring units 18 are configured to project measuring beams to lower surface of the first substrate 121 placed on the carrier surface 151 of the carrier 15, and measure the distances between the first substrate 121 and each distance measuring unit 18.

Specifically, if the distances between the first substrate 121 and each distance measuring units 18 are similar, it can be determined that the first substrate 121 is not warped. Then the alignment units 14 are able to align the first substrate 121 without the need to flatten the first substrate 121 through the flattening devices 17. The second substrate 123 is placed on the first substrate 121, and the alignment units 14 align the second substrate 123 with the first substrate 121. Thereafter, the pressing unit 13 presses and bonds the first substrate 121 and the second substrate 123.

Conversely, if the distance difference between the first substrate 121 and each distance measuring unit 18 is greater than a threshold value, it can be determined that the first substrate 121 is warped. Then, the flattening devices 17 flatten the first substrate 121, before aligning the first substrate 121. For example, the flattening steps in FIGS. 4, 7 and 8 are performed.

After the flattening and alignment of the first substrate 121 is completed, the flattening unit 173 will move away from the first substrate 121 and the placement area 153, as shown in FIG. 6 and FIG. 4. Specifically, the telescopic rotary motor 171 extends and drives the flattening unit 173 to move away from the first substrate 121 along the axial direction of the carrier surface 151, and then the telescopic rotary motor 171 drives the flattening unit 173 to swing, and drives the flattening unit 173 to leave above the first substrate 121 and/or the placement area 153.

After the alignment of the first substrate 121 is completed, the second substrate 123 is placed on the first substrate 121. The alignment unit 14 is configured to align the second substrate 123 with the first substrate 121, and then the pressing unit 13 presses and bonds the first substrate 121 and the second substrate 123.

In the drawings of this disclosure, the rod 175 of the flattening device 17 or the telescopic rotary motor 171 passes through the second chamber 113 and the carrier 15, and is connected to the flattening unit 173 on the carrier surface 151. In other embodiment of this disclosure, the rod 175, the telescopic rotary motor 171 and/or the flattening unit 173 may be arranged around the carrier 15, and the telescopic rotary motor 171 and/or the rod 175 only pass through the second chamber 113 without passing through the carrier 15.

Accordingly, the flattening units 173 operating at the first position will be located outside the carrier surface 151 and/or the placing area 153 of the carrier 15 without overlapping or interfering with the carrier surface 151 and the first substrate 121. Furthermore, the flattening units 173 operating at the second position will enter the carrier surface 151 and/or the placing area 153 of the carrier 15, and locate above the carrier surface 151 and the first substrate 121 to flatten the first substrate 121 on the carrier surface 151 of the carrier 15.

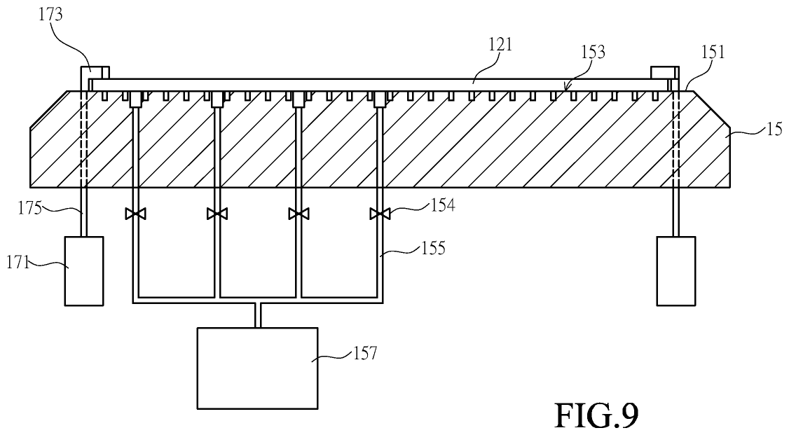

As shown in FIG. 5, FIG. 6 and FIG. 9, the carrier 15 may include a plurality of exhaust lines 155 that are arranged in the carrier 15. For example, the exhaust lines 155 pass through the carrier 15, and one end of the exhaust lines 155 connects with the carrier surface 151 and/or the placement area 153 of the carrier 15. The exhaust lines 155 are connected to an air extraction device 157, such as an air extraction motor. When the air extraction device 157 is operating, the exhaust lines 155 connected to the carrier surface 151 and/or the placement area 153 will form a negative pressure to suck and flatten the first substrate 121 placed on the placement area 153 of the carrier 15.

In one embodiment of this disclosure, each exhaust line 155 may generate negative pressure at the same time, and suck the first substrate 121 on the placement area 153. In other embodiment of this disclosure, each exhaust line 155 may be respectively connected to a valve 154. The valves 154 are configured to control the exhaust lines 155 to generate negative pressure at different times. For example, the exhaust lines 155 located on the inner side generates negative pressure first, and sucks and flattens the inner side of the first substrate 121. Then, the other exhaust lines 155 sequentially generate negative pressure along the direction from the center of the placement area 153 to the edge, so as to suck and flatten the outside of the first substrate 121.

Specifically, the flattening unit 173 is configured to flatten the side edge or outer edge of the first substrate 121, and the negative pressure generated by the exhaust lines 155 is configured to suck and flatten the inner side of the first substrate 121. Through the combination of the flattening unit 173 and the exhaust lines 155, the flatness and the alignment accuracy of the first substrate 121 can be further improved. In addition, during the alignment of the first substrate 121 and/or the second substrate 123 by the alignment units 14, the exhaust lines 155 will not suck the first substrate 121. Thus, the alignment unit 14 is able to move or push the first substrate 121 on the carrier surface 151 of the carrier 15, and perform the alignment of the first substrate 121.

The above description is only a preferred embodiment of this disclosure, and is not intended to limit the scope of this disclosure. Modifications should be included within the scope of the patent application of this disclosure.

What is claimed is:

1. A bonding machine for warped substrates, comprising:
a first chamber;
a second chamber facing the first chamber, wherein the first chamber is configured to be connected the second chamber to define an enclosed space between the first chamber and the second chamber;
a pressing unit connected to the first chamber and located within the enclosed space;
a carrier connected to the second chamber, and located within the enclosed space, wherein the carrier includes a carrier surface facing the pressing unit, wherein the carrier surface includes a placement area is configured to carry a first substrate, and a second substrate is placed on the first substrate; and
a plurality of flattening devices, including:
a plurality of flattening units located around the placement area of the carrier;
a plurality of telescopic rotary motors connected to the flattening units, and driving the flattening units to swing, move up and down relative to the carrier surface of the carrier, so that the flattening units are configured to flatten the first substrate on the placement area.

2. The bonding machine for warped substrates according to claim 1, further comprising a plurality of exhaust lines disposed in the carrier and connected to the placement area of the carrier, wherein the exhaust lines are configured to form a negative pressure to suck the first substrate on the placement area.

3. The bonding machine for warped substrates according to claim 2, further comprising an air extraction device and a plurality of valves, wherein the air extraction device is connected to the exhaust lines to form the negative pressure on the exhaust lines connected to the placement area, and the valves are respectively connected to the exhaust lines, and configured to switch whether the exhaust lines generate the negative pressure.

4. The bonding machine for warped substrates according to claim 2, further comprising a plurality of alignment units arranged on the carrier surface of the carrier and surrounding the placement area of the carrier, wherein the alignment units are configured to align the first substrate and the second substrate, and during the process of alignment of the first substrate or the second substrate by the alignment unit, the exhaust line will not suck the first substrate.

5. The bonding machine for warped substrates according to claim 4, wherein the alignment unit is connected to a linear actuator, and is driven by the linear actuator to moves up and down relative to the carrier surface of the carrier.

6. The bonding machine for warped substrates according to claim 2, wherein the flattening units are configured to flatten a side edge of the first substrate, and the negative pressure generated by the exhaust lines are configured to suck an inner side of the first substrate.

7. The bonding machine for warped substrates according to claim 1, further comprising a plurality of rods passing through the carrier and the second chamber, wherein the telescopic rotary motors are located outside the enclosed space, and respectively connected to the flattening units through the rods to drive the flattening units to swing, move up and down relative to the carrier surface of the carrier.

8. The bonding machine for warped substrates according to claim 1, wherein the telescopic rotary motor includes a linear actuator and a rotation motor, and the linear actuator is connected to the flattening unit via the rotation motor.

9. The bonding machine for warped substrates according to claim 1, wherein the telescopic rotary motor is configured to drive the flattening unit to swing between a first position and a second position, the flattening unit operating at the first position is located outside the placement area, and the flattening unit operating at the second position is located above the placement area.

10. The bonding machine for warped substrates according to claim 9, wherein the telescopic rotary motor is configured to drive the flattening unit to move between a first height and a second height, and the first height is higher than the second height.

11. The bonding machine for warped substrates according to claim 10, wherein a gap is formed between the flattening unit operating at the first height and the carrier surface of the carrier, and the gap is larger than a thickness of the first substrate plus a warpage of the first substrate, wherein the flattening unit operating at the second height contacts and flattens the first substrate placed on the carrier surface.

12. The bonding machine for warped substrates according to claim 1, further comprising a plurality of distance measuring units arranged on the pressing unit for measuring distances between each distance measuring unit and the first substrate.

13. The bonding machine for warped substrates according to claim 12, wherein the distance measuring unit is a laser rangefinder.

14. The bonding machine for warped substrates according to claim 1, wherein the pressing unit includes a pressing plate, a connecting plate and a plurality of fixing rods, the connecting plate is connected to the pressing plate through the fixing rods, and the pressing plate faces the carrier surface of the carrier.

15. The bonding machine for warped substrates according to claim 1, further comprising a chamber driver located outside the enclosed space, and connecting to and driving the first chamber to move relative to the second chamber.

16. The bonding machine for warped substrates according to claim 15, further comprising a pressing unit driver located outside the enclosed space, and connecting to and driving the pressing unit to move toward or move away from the carrier.

17. The bonding machine for warped substrates according to claim 1, further comprising an air extraction motor fluidly connected to the enclosed space.

18. The bonding machine for warped substrates according to claim 1, further comprising a first heating unit arranged in the carrier.

19. The bonding machine for warped substrates according to claim 18, further comprising a second heating unit arranged in the pressing unit.

20. The bonding machine for warped substrates according to claim 1, further comprising a plurality of rods passing through the second chamber and arranged around the carrier, wherein the telescopic rotary motors are located outside the enclosed space, and respectively connected to the flattening units through the rods to drive the flattening units to swing, move up and down relative to the carrier surface of the carrier.
